(19) United States
(12) Patent Application Publication
(10) Pub. No.: US 2025/0266798 A1
(43) Pub. Date: Aug. 21, 2025

(54) SEMICONDUCTOR DEVICE

(71) Applicant: Hitachi Astemo, Ltd., Hitachinaka-shi, Ibaraki (JP)

(72) Inventors: Minoru MIGITA, Hitachinaka-shi, Ibaraki (JP); Yuzuru TAKASHIMA, Hitachinaka-shi, Ibaraki (JP)

(73) Assignee: Hitachi Astemo, Ltd., Hitachinaka-shi, Ibaraki (JP)

(21) Appl. No.: 18/859,480

(22) PCT Filed: Apr. 28, 2022
(86) PCT No.: PCT/JP2022/019397

§ 371 Date: Oct. 23, 2024

(51) Int. Cl. H03F 3/45; H05K 1/18

(52) U.S. Cl. CPC H03F 3/45475; H05K 1/181

(57) ABSTRACT

Provided is a voltage sense IC that is mounted on a PCB substrate to detect a power supply voltage, the voltage sense IC being capable of reducing the area of the PCB substrate and reducing the types of mounted components. A semiconductor device includes: a first input terminal connected to one potential of a voltage to be monitored; a second input terminal connected to another potential of the voltage to be monitored; a voltage dividing resistor that divides a voltage between the first input terminal and the second input terminal; a polarity switching unit connected to the voltage dividing resistor; and an amplifier circuit connected to the polarity switching unit. The polarity switching unit switches polarities of a first path and a second path from the voltage dividing resistor provided between the voltage dividing resistor and the amplifier circuit to the amplifier circuit based on polarity setting information.

### TECHNICAL FIELD

The present invention relates to a configuration of a semiconductor device, and particularly relates to an effective technique applied to a voltage sense IC that is mounted on a printed circuit board and detects a power supply voltage.

### BACKGROUND ART

In an electric vehicle, a monitoring function of a high voltage for driving a motor supplied from a battery is essential. In order to monitor the voltage of the battery, it is necessary to route and connect the voltage node to be monitored to an area having a voltage monitoring function by wiring or the like.

As a background art of the present technical field, for example, there is a technique such as PTL 1. PTL 1 discloses “A voltage detection device capable of securing predetermined insulation performance while suppressing an increase in a mounting area on a printed wiring board when a plurality of voltage detection circuits are mounted on the printed wiring board”.

In PTL 1, two voltage detection circuits (a first voltage detection circuit 1 and a second voltage detection circuit 2) are mounted close to a printed wiring board 4, an input terminal 12 of the first voltage detection circuit 1 and an input terminal 22 of the second voltage detection circuit 2 are electrically connected, and a negative voltage is input to both the input terminal 12 and the input terminal 22. (FIG. 3 and paragraphs to of PTL 1)

### CITATION LIST

### Patent Literature

PTL 1: JP 2019-178885 A

### SUMMARY OF INVENTION

### Technical Problem

Meanwhile, in the automobile field, downsizing and weight reduction of various in-vehicle units, and reduction of types and quantities of used parts have been continuous problems.

Since the above-described voltage monitoring function is generally configured by an electronic component and mounted on a printed circuit board (hereinafter, referred to as a “PCB substrate”), the voltage node to be monitored is wired on the PCB substrate. However, in order to avoid a proximity short circuit of wiring on the PCB substrate, it is necessary to secure a distance between wiring lines between voltage nodes corresponding to a maximum voltage to be monitored. For this reason, a decrease in the degree of freedom in designing the PCB pattern due to the high-voltage wiring on the PCB substrate becomes an alienation of a reduction in the area of the PCB substrate.

In addition, in a case where two voltage sense ICs are used to detect two different types of voltages, it is necessary to design a PCB pattern so as to avoid proximity short circuit of the voltage input terminals of the voltage sense ICs. In a case where the positive terminals and the negative terminals of the voltage input terminals of the two types of voltage sense ICs are arranged in the same order, when the voltage sense ICs are arranged side by side, one of the voltage input terminals of the voltage sense IC on one side and the voltage input terminal of the adjacent voltage sense IC is on the positive side and the other is on the negative side. Therefore, the voltage sense ICs cannot be arranged close to each other in order to avoid proximity short circuit of the voltage input terminal, which causes a decrease in the degree of freedom in designing the PCB pattern. In order to arrange the voltage sense ICs close to each other, it is necessary to use two types of voltage sense ICs having different arrangement orders of the positive side and the negative side of the voltage input terminals of the voltage sense ICs, that is, having different input polarities.

In PTL 1, a negative voltage is input to the input terminal 12 of the first voltage detection circuit 1, and a positive voltage is input to the input terminal 11. On the other hand, the negative electrode voltage is input to the input terminal 22 of the second voltage detection circuit 2, and the positive electrode voltage is input to the input terminal 21.

Therefore, it is necessary to change the internal circuit configuration in the first voltage detection circuit 1 and the second voltage detection circuit 2, and the same voltage detection circuit cannot be used.

Therefore, an object of the present invention is to provide a voltage sense IC that is mounted on a PCB substrate and detects a power supply voltage, a voltage sense IC being capable of reducing the area of the PCB substrate and reducing the types of mounted components.

### Solution to Problem

In order to solve the above problem, the present invention includes: a first input terminal connected to one potential of a voltage to be monitored; a second input terminal connected to another potential of the voltage to be monitored; a voltage dividing resistor that divides a voltage between the first input terminal and the second input terminal; a polarity switching unit connected to the voltage dividing resistor; and an amplifier circuit connected to the polarity switching unit, in which the polarity switching unit switches polarities of a first path and a second path from the voltage dividing resistor provided between the voltage dividing resistor and the amplifier circuit to the amplifier circuit based on polarity setting information.

### Advantageous Effects of Invention

According to the present invention, in a voltage sense IC that is mounted on a PCB substrate and detects a power supply voltage, it is possible to realize a voltage sense IC capable of reducing the area of the PCB substrate and reducing the types of mounted components.

As a result, it is possible to reduce the size and weight of the PCB substrate on which the voltage sense IC is mounted and to reduce the cost by reducing the types of mounted components.

Problems, configurations, and effects other than those described above will be clarified by the following description of embodiments.

### BRIEF DESCRIPTION OF DRAWINGS

FIG. 1 is a diagram illustrating a schematic configuration of a semiconductor device according to a first embodiment of the present invention.

FIG. 2 is a diagram illustrating a schematic configuration of a semiconductor device according to a second embodiment of the present invention.

FIG. 3 is a diagram illustrating a schematic configuration of a semiconductor device according to a third embodiment of the present invention.

FIG. 4 is a diagram illustrating a schematic configuration of a semiconductor device according to a fourth embodiment of the present invention.

FIG. 5A is a diagram illustrating a schematic configuration of a semiconductor device according to a fifth embodiment of the present invention.

FIG. 5B is a diagram illustrating a state in which a voltage source having a polarity opposite to that in FIG. 5A is connected.

FIG. 6A is a diagram illustrating a schematic configuration of a semiconductor device according to a sixth embodiment of the present invention.

FIG. 6B is a diagram illustrating a state in which a voltage source having a polarity opposite to that in FIG. 6A is connected.

FIG. 7A is a diagram illustrating a schematic configuration of a semiconductor device according to a seventh embodiment of the present invention.

FIG. 7B is a diagram illustrating a semiconductor device mounted on the back surface of a PCB substrate of FIG. 7A.

FIG. 8 is a diagram illustrating a schematic configuration of a semiconductor device according to an eighth embodiment of the present invention.

### DESCRIPTION OF EMBODIMENTS

Hereinafter, embodiments of the present invention will be described with reference to the drawings. In the drawings, the same components are denoted by the same reference numerals, and the detailed description of overlapping components is omitted.

### First Embodiment

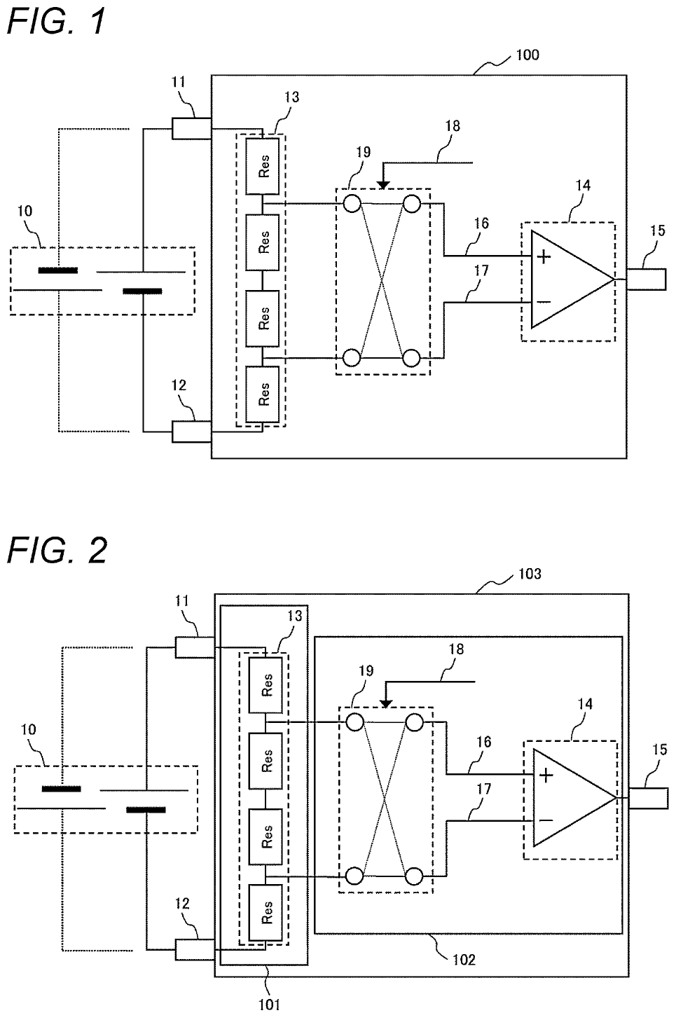

A semiconductor device according to a first embodiment of the present invention will be described with reference to FIG. 1. FIG. 1 is a diagram illustrating a schematic configuration of a semiconductor device 100 according to the present embodiment.

As illustrated in FIG. 1, the semiconductor device 100 (voltage sense IC) of the present embodiment includes an input terminal 11, an input terminal 12, a voltage dividing resistor 13, an amplifier circuit 14, an output terminal 15, and a polarity switching unit 19 as a main configuration.

The input terminal 11 is connected to one potential (for example, a positive electrode) of a voltage source 10 to be monitored, and the input terminal 12 is connected to the other potential (for example, a negative electrode) of the voltage source 10.

The voltage dividing resistor 13 divides the voltage input to the input terminal 11 and the input terminal 12.

The amplifier circuit 14 is disposed downstream of the voltage dividing resistor 13 in the direction of the current flowing in the semiconductor device 100, amplifies information regarding the potential difference between one potential (for example, the positive electrode) and the other potential (for example, the negative electrode) of the voltage source 10 obtained from the voltage dividing resistor 13, and outputs the amplified information as potential difference information from the output terminal 15.

The voltage dividing resistor 13 and the amplifier circuit 14 are connected by a first path 16 and a second path 17 via a polarity switching unit 19. The voltage dividing resistor 13 inputs information regarding the potential difference to the amplifier circuit 14 via the first path 16 and the second path 17.

The polarity switching unit 19 is provided between the voltage dividing resistor 13 and the amplifier circuit 14, and switches the polarities of the first path 16 and the second path 17 to the amplifier circuit 14 according to the input polarity setting information 18 to fix the polarities of the first path 16 and the second path 17.

In a case where the polarity of the voltage source 10 to be monitored is opposite, that is, in a case where the input terminal 11 is connected to the negative electrode and the input terminal 12 is connected to the positive electrode as indicated by a dotted line in FIG. 1, the polarities of the first path 16 and the second path 17 are switched and fixed by the polarity switching unit 19 according to the polarity setting information 18 for switching the polarities of the first path 16 and the second path 17 to the amplifier circuit 14.

As described above, the semiconductor device 100 (voltage sense IC) of the present embodiment includes the input terminal 11 (first input terminal) connected to one potential of the voltage source 10 to be monitored, the input terminal 12 (second input terminal) connected to the other potential of the voltage source 10, the voltage dividing resistor 13 that divides the voltage between the input terminal 11 (first input terminal) and the input terminal 12 (second input terminal), the polarity switching unit 19 connected to the voltage dividing resistor 13, and the amplifier circuit 14 connected to the polarity switching unit 19, and the polarity switching unit 19 switches the polarities of the first path 16 and the second path 17, which are provided between the voltage dividing resistor 13 and the amplifier circuit 14, from the voltage dividing resistor 13 provided to the amplifier circuit 14 based on the polarity setting information 18.

As a result, since the polarities of the input terminal 11 and the input terminal 12 of the semiconductor device 100 (voltage sense IC) can be set in accordance with the layout of the wiring on the PCB substrate and the polarity of the battery to be connected, routing of the wiring on the PCB substrate is facilitated, and the degree of freedom in designing the PCB substrate is improved.

### Second Embodiment

A semiconductor device according to a second embodiment of the present invention will be described with reference to FIG. 2. FIG. 2 is a diagram illustrating a schematic configuration of a semiconductor device 103 of the present embodiment, and corresponds to a modification of the first embodiment (FIG. 1).

In the semiconductor device 103 (voltage sense IC) of the present embodiment, as illustrated in FIG. 2, the voltage dividing resistor 13 is configured by a high-voltage device 101, the amplifier circuit 14 and the polarity switching unit 19, and the first path 16 and the second path 17 are configured by a low-voltage device 102, and the high-voltage device 101 and the low-voltage device 102 are configured by one package of a multi chip package (MCP).

The voltage dividing resistor 13 that divides a high voltage is configured by the high-voltage device 101 (first chip) that operates at a relatively high voltage, and the amplifier circuit 14 and the polarity switching unit 19 that detect a potential after being divided by the voltage dividing resistor 13 are configured by the low-voltage device 102 (second chip) that operates at a voltage lower than that of the high-voltage device 101.

In general, an element size (chip size) of a high-voltage device is larger than that of a low-voltage device in order to secure a withstand voltage. By configuring the voltage dividing resistor 13 to which a high voltage is applied and the amplifier circuit 14 and the polarity switching unit 19 to which a relatively low voltage after voltage division is applied as in the present embodiment (FIG. 2) by separate chips, the chips on which the amplifier circuit 14 and the polarity switching unit 19 are mounted can be reduced in size (or thinned), so that the entire semiconductor device can be downsized as compared with the case where the entire circuit is configured by a high-voltage device as in the first embodiment (FIG. 1).

### Third Embodiment

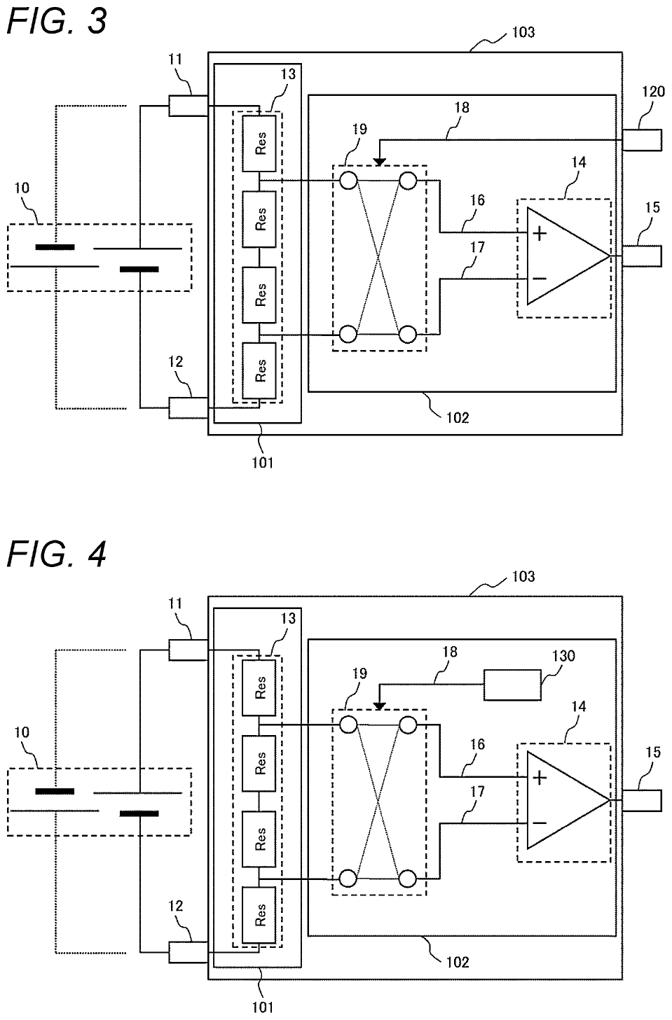

A semiconductor device according to a third embodiment of the present invention will be described with reference to FIG. 3. FIG. 3 is a diagram illustrating a schematic configuration of the semiconductor device 103 of the present embodiment, and corresponds to a modification of the second embodiment (FIG. 2).

As illustrated in FIG. 3, the semiconductor device 103 (voltage sense IC) of the present embodiment includes a polarity setting terminal 120 for inputting the polarity setting information 18 from the outside to the polarity switching unit 19.

The polarity switching unit 19 switches the polarities of the first path 16 and the second path 17 to the amplifier circuit 14 according to the polarity setting information 18 input via the polarity setting terminal 120, and fixes the polarities of the first path 16 and the second path 17.

The polarities of the first path 16 and the second path 17 can be selected according to the voltage state of the polarity setting terminal 120, and when the semiconductor device 103 is mounted on a substrate (not illustrated), the polarity setting terminal 120 is connected to a fixed potential on the substrate, whereby the polarities of the first path 16 and the second path 17 are selected and fixed.

With the above configuration, the polarity of the path of the polarity switching unit 19 is fixed when the semiconductor device 103 (voltage sense IC) is mounted on the substrate, and erroneous polarity setting can be prevented.

### Fourth Embodiment

A semiconductor device according to a fourth embodiment of the present invention will be described with reference to FIG. 4. FIG. 4 is a diagram illustrating a schematic configuration of the semiconductor device 103 of the present embodiment, and corresponds to a modification of the third embodiment (FIG. 3).

As illustrated in FIG. 4, the semiconductor device 103 (voltage sense IC) of the present embodiment includes a nonvolatile memory 130 for storing the polarity setting information 18 in the semiconductor device 103.

The polarity switching unit 19 switches the polarities of the first path 16 and the second path 17 to the amplifier circuit 14 according to the polarity setting information 18 read from the nonvolatile memory 130, and fixes the polarities of the first path 16 and the second path 17.

With the above configuration, it is possible to suppress the influence of disturbance and noise on the polarity setting information 18.

### Fifth Embodiment

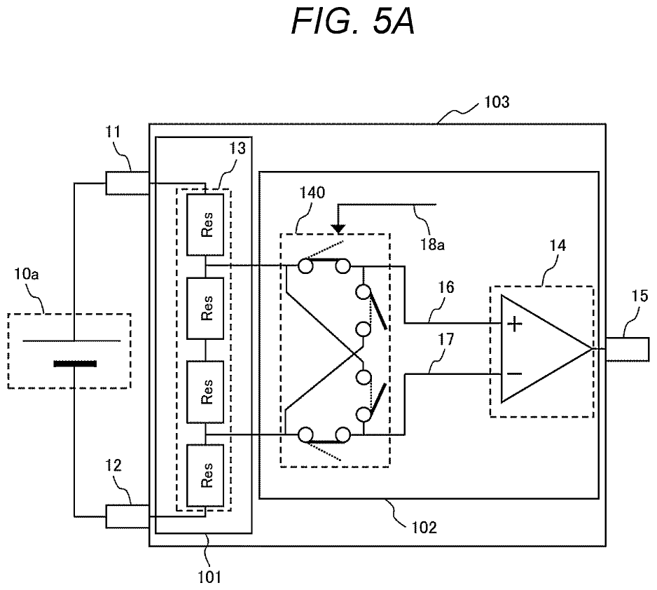

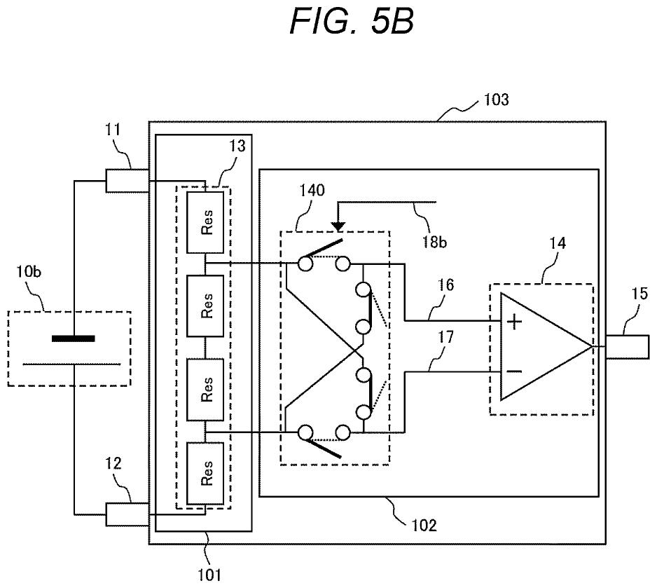

A semiconductor device according to a fifth embodiment of the present invention will be described with reference to FIGS. 5A and 5B. FIGS. 5A and 5B are diagrams illustrating a schematic configuration of the semiconductor device 103 of the present embodiment, and correspond to a modification of the second embodiment (FIG. 2).

FIG. 5A illustrates a state in which the positive electrode of a voltage source 10a is connected to the input terminal 11 and the negative electrode of the voltage source 10a is connected to the input terminal 12. On the other hand, FIG. 5B illustrates a state in which the negative electrode of a voltage source 10b is connected to the input terminal 11 and the positive electrode of the voltage source 10b is connected to the input terminal 12.

In the semiconductor device 103 (voltage sense IC) of the present embodiment, as illustrated in FIGS. 5A and 5B, a polarity switching unit 140 includes a plurality of switches that electrically switches the polarities of the first path 16 and the second path 17.

In FIG. 5A, a positive electrode side of the voltage source 10a to be monitored is connected to the input terminal 11 of the semiconductor device 103, and a negative electrode side of the voltage source 10a is connected to the input terminal 12 of the semiconductor device 103. The state of each switch of the polarity switching unit 140 is determined based on polarity setting information 18a, the potential information of the input terminal 11 resistance-divided by the voltage dividing resistor 13 is connected to the first path 16, and the potential information of the input terminal 12 is connected to the second path 17.

In FIG. 5B, a positive electrode side of the voltage source 10b to be monitored is connected to the input terminal 12 of the semiconductor device 103, and a negative electrode side of the voltage source 10b is connected to the input terminal 11 of the semiconductor device 103. The state of each switch of the polarity switching unit 140 is determined based on polarity setting information 18b, the potential information of the input terminal 12 resistance-divided by the voltage dividing resistor 13 is connected to the first path 16, and the potential information of the input terminal 11 is connected to the second path 17.

As in the present embodiment, by mounting a plurality of switches for electrically switching the polarities of the first path 16 and the second path 17 on the low-voltage device (chip) 102 as the polarity switching unit 140, the size of the polarity switching unit can be significantly reduced as compared with a case where a switching switch is configured outside the low-voltage device 102 and the polarities of the first path 16 and the second path 17 are switched based on polarity setting information input from the outside, and the entire semiconductor device 103 can be downsized.

### Sixth Embodiment

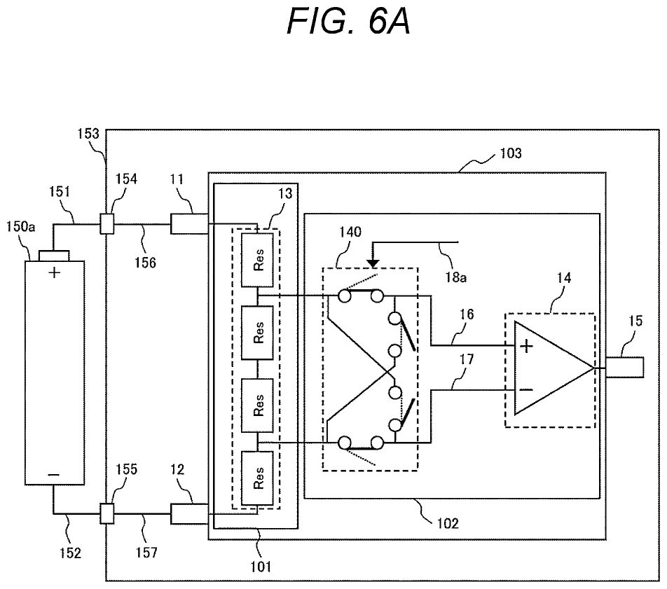

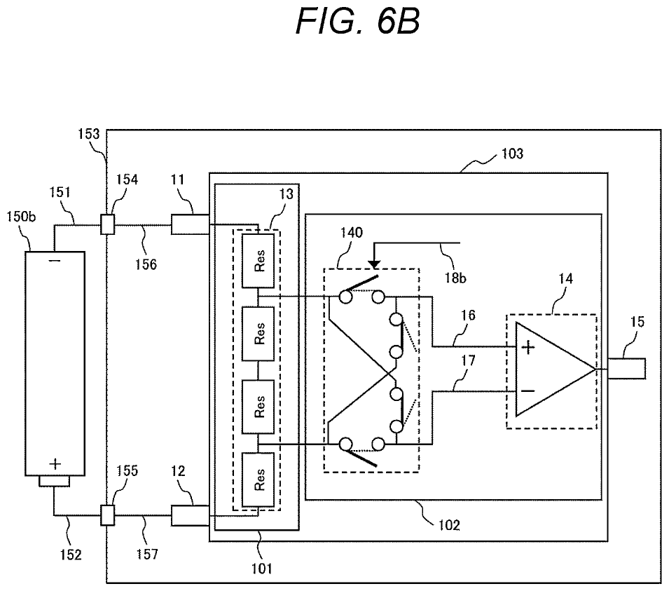

A semiconductor device according to a sixth embodiment of the present invention will be described with reference to FIGS. 6A and 6B. FIGS. 6A and 6B are diagrams illustrating a schematic configuration of the semiconductor device 103 of the present embodiment, and correspond to a modification of the fifth embodiment (FIGS. 5A and 5B).

In the present embodiment, a case where the semiconductor device 103 is mounted on a PCB substrate 153 will be described.

In FIG. 6A, the potential on the positive electrode side of a voltage source 150a to be monitored is connected to a terminal 154 of the PCB substrate 153 by a connection wiring 151 such as a harness or a bus bar, and the potential on the negative electrode side of the voltage source 150a is connected to a terminal 155 of the PCB substrate 153 by a connection wiring 152 such as a harness or a bus bar.

The terminal 154 of the PCB substrate 153 and the input terminal 11 of the semiconductor device 103 are connected by a wiring 156 on the PCB substrate 153, and the terminal 155 of the PCB substrate 153 and the input terminal 12 of the semiconductor device 103 are connected by a wiring 157 on the PCB substrate 153.

The state of each switch of the polarity switching unit 140 is determined based on the polarity setting information 18a, the potential information of the input terminal 11 resistance-divided by the voltage dividing resistor 13 is connected to the first path 16, and the potential information of the input terminal 12 is connected to the second path 17.

In FIG. 6B, the potential on the positive electrode side of a voltage source 150b to be monitored is connected to the terminal 155 of the PCB substrate 153 by the connection wiring 152 such as a harness or a bus bar, and the potential on the negative electrode side of the voltage source 150b is connected to the terminal 154 of the PCB substrate 153 by the connection wiring 151 such as a harness or a bus bar.

The terminal 154 of the PCB substrate 153 and the input terminal 11 of the semiconductor device 103 are connected by a wiring 156 on the PCB substrate 153, and the terminal 155 of the PCB substrate 153 and the input terminal 12 of the semiconductor device 103 are connected by a wiring 157 on the PCB substrate 153.

The state of each switch of the polarity switching unit 140 is determined based on polarity setting information 18b, the potential information of the input terminal 12 resistance-divided by the voltage dividing resistor 13 is connected to the first path 16, and the potential information of the input terminal 11 is connected to the second path 17.

As described above, the semiconductor device 103 of the present embodiment is mounted on the PCB substrate 153 by switching the polarities of the first path 16 and the second path 17 based on the polarities of the two potential signals input to the input terminal 11 and the input terminal 12.

By mounting the semiconductor device 103 including the polarity switching unit 140 on the PCB substrate 153 as the voltage sense IC as in the present embodiment, it is possible to improve the degree of freedom of arrangement of the voltage source to be monitored and the semiconductor device 103. In addition, the degree of freedom of routing of the connection wirings 151 and 152 such as a harness or a bus bar, which is a voltage node to be monitored, and routing of the wirings 156 and 157 on the PCB substrate 153 can be improved.

### Seventh Embodiment

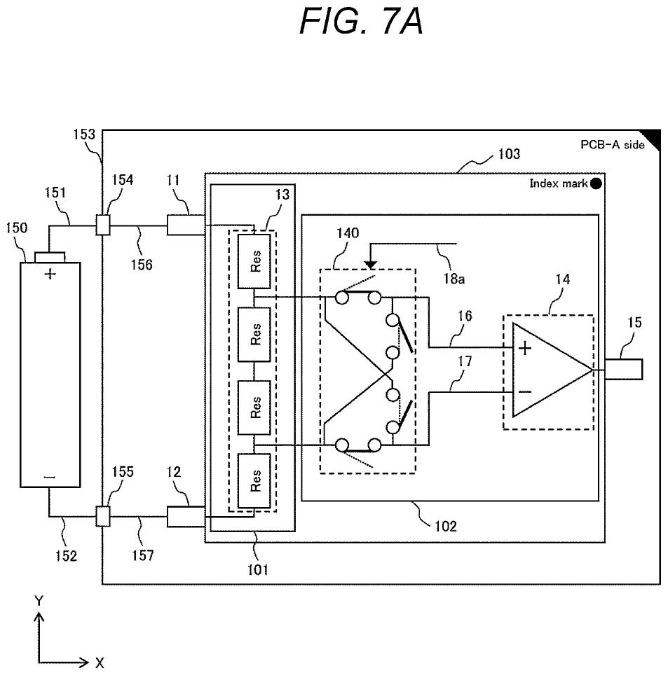

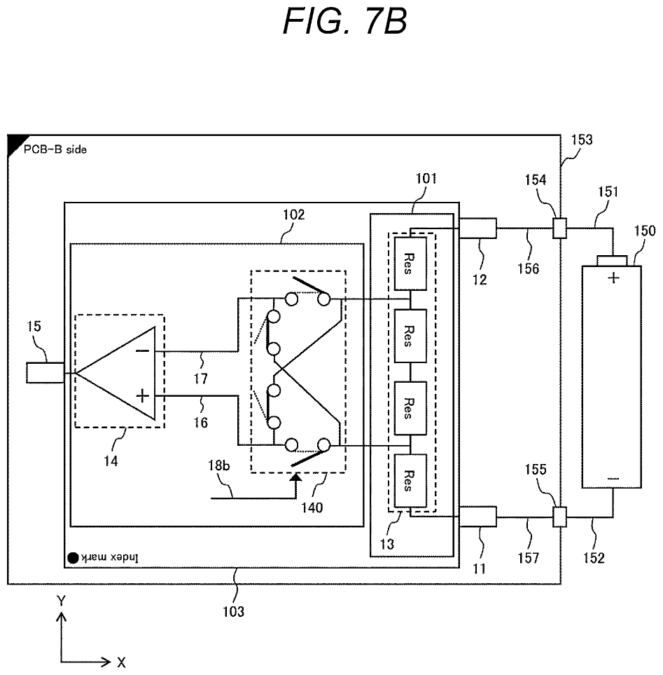

A semiconductor device according to a seventh embodiment of the present invention will be described with reference to FIGS. 7A and 7B. FIGS. 7A and 7B are diagrams illustrating a schematic configuration of the semiconductor device 103 of the present embodiment, and correspond to a modification of the sixth embodiment (FIGS. 6A and 6B).

In the present embodiment, a case where the semiconductor device 103 is mounted on one or both of the front surface (A surface) and the back surface (B surface) of the PCB substrate 153 will be described.

FIG. 7A basically has the same configuration as FIG. 6A, but “PCB-A side” is written on the PCB substrate 153 to indicate that the semiconductor device 103 is mounted on the front surface (A surface) of the PCB substrate 153. In addition, an index mark is written on the upper right of the semiconductor device 103 to indicate the orientation of the semiconductor device 103.

FIG. 7B illustrates a state in which the semiconductor device 103 is mounted on the back surface (B surface) of the PCB substrate 153 of FIG. 7A. In FIG. 7B, the polarity of the voltage source 150 to be monitored is the same as that in FIG. 7A, expressing the case of folding back FIG. 7A along the X axis. In FIG. 7A, the semiconductor device 103 is rotated by 180° (upside down) and mounted on the back surface (B surface) of the PCB substrate 153, and the state of each switch of the polarity switching unit 140 is changed from that in FIG. 7A based on the polarity setting information 18b.

According to the present embodiment, it is possible to select the mounting surface of the semiconductor device 103 on the PCB substrate 153, and it is possible to improve the degree of freedom of arrangement of the voltage source to be monitored and the semiconductor device 103. In addition, the degree of freedom of routing of the connection wirings 151 and 152 such as a harness or a bus bar, which is a voltage node to be monitored, and routing of the wirings 156 and 157 on the PCB substrate 153 can be improved.

### Eighth Embodiment

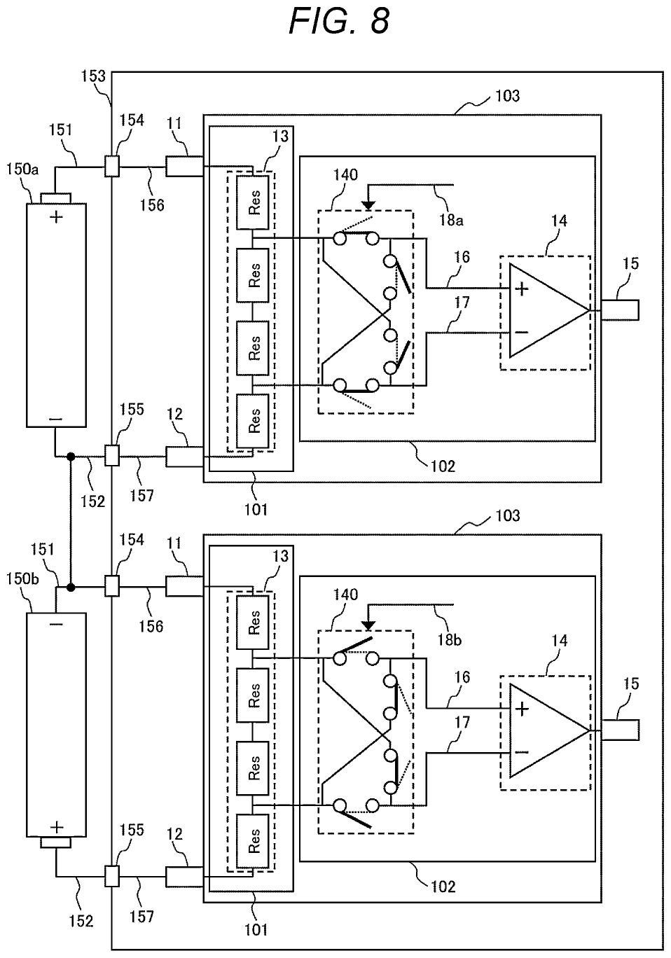

A semiconductor device according to an eighth embodiment of the present invention will be described with reference to FIG. 8. FIG. 8 is a diagram illustrating a schematic configuration of the semiconductor device 103 of the present embodiment, and corresponds to a modification of the sixth embodiment (FIGS. 6A and 6B).

In the present embodiment, a case where two semiconductor devices 103 illustrated in FIGS. 6A and 6B are mounted on the same surface of the same PCB substrate 153 will be described.

In FIG. 8, the upper semiconductor device 103 has the same configuration as that in FIG. 6A, and the lower semiconductor device 103 has the same configuration as that in FIG. 6B.

As illustrated in FIG. 8, in a case where the potential differences between the two types of voltage sources 150a and 150b are detected, in a case where one of the two types of potential differences has the same potential (in FIG. 8, the potential of the negative electrode of the voltage source 150a and the potential of the negative electrode of the voltage source 150b have the same potential), the connection to the amplifier circuit 14 that detects the potential difference between the two potential signals is changed by the two semiconductor devices 103, so that the two types of potential differences can be detected by the one type of semiconductor device 103.

Note that, in FIG. 8, the two semiconductor devices 103 are arranged such that the input terminals 12 and 11 having the same potential are adjacent to each other, and the wirings 157 and 156 on the PCB substrate are connected by wiring.

As described above, in the present embodiment, the plurality of semiconductor devices 103 are mounted on the same surface of the same PCB substrate 153, and the polarities of the first paths 16 and the second paths 17 of at least some of the semiconductor devices 103 are different from those of the other semiconductor devices 103.

As in the present embodiment, for example, in a case where two different types of voltages are detected, one type of two semiconductor devices 103 having the polarity switching unit 140 are used, and the polarities are selected so that the arrangement of the input terminals 11 and 12 of the respective semiconductor devices 103 is optimized, whereby the two semiconductor devices 103 can be arranged close to each other. In addition, as in other embodiments, it is possible to improve the degree of freedom of routing of the connection wirings 151 and 152 such as a harness or a bus bar, which is a voltage node to be monitored, and the wirings 156 and 157 on the PCB substrate 153.

Note that the present invention is not limited to the above-described embodiments, and includes various modifications. For example, the above-described embodiments have been described in detail for easy understanding of the present invention, and are not necessarily limited to those having all the described configurations. In addition, a part of the configuration of a certain embodiment can be replaced with the configuration of another embodiment, and the configuration of another embodiment can be added to the configuration of a certain embodiment. In addition, it is possible to add, delete, and replace other configurations for a part of the configuration of each embodiment.

### REFERENCE SIGNS LIST

10, 10a, 10b, 150, 150a, 150b voltage source
11, 12 input terminal
13 voltage dividing resistor
14 amplifier circuit
15 output terminal
16 first path
17 second path
18, 18a, 18b polarity setting information
19, 140 polarity switching unit
100, 103 semiconductor device (voltage sense IC)
101 high-voltage device
102 low-voltage device
120 polarity setting terminal
130 nonvolatile memory
151, 152 connection wiring
153 PCB substrate
154, 155 terminal of PCB substrate
156, 157 wiring on PCB substrate

1. A semiconductor device comprising:
a first input terminal connected to one potential of a voltage to be monitored;
a second input terminal connected to another potential of the voltage to be monitored;
a voltage dividing resistor that divides a voltage between the first input terminal and the second input terminal;
a polarity switching unit connected to the voltage dividing resistor; and
an amplifier circuit connected to the polarity switching unit,
wherein the polarity switching unit switches polarities of a first path and a second path from the voltage dividing resistor provided between the voltage dividing resistor and the amplifier circuit to the amplifier circuit based on polarity setting information.

2. The semiconductor device according to claim 1, wherein
the semiconductor device includes a multi chip package (MCP) in which a first chip and a second chip operating at a lower voltage than the first chip are included in one package,
the voltage dividing resistor is disposed on the first chip, and
the polarity switching unit and the amplifier circuit are disposed on the second chip.

3. The semiconductor device according to claim 1, comprising a polarity setting terminal to which the polarity setting information is input,
wherein polarities of the first path and the second path can be selected according to a voltage state of the polarity setting terminal, and
when the semiconductor device is mounted on a substrate, the polarity setting terminal is connected to a fixed potential on the substrate to select and fix polarities of the first path and the second path.

4. The semiconductor device according to claim 1, comprising a nonvolatile memory that stores the polarity setting information.

5. The semiconductor device according to claim 1, wherein the polarity switching unit includes a plurality of switches that electrically switch polarities of the first path and the second path.

6. The semiconductor device according to claim 1, wherein polarities of the first path and the second path are switched based on polarities of two potential signals input to the first input terminal and the second input terminal, and the semiconductor device is mounted on a PCB substrate.

7. The semiconductor device according to claim 6, wherein the semiconductor device is mounted on any one or both of a front surface and a back surface of the PCB substrate.

8. The semiconductor device according to claim 1, wherein
a plurality of the semiconductor devices are mounted on a same surface of a same PCB substrate, and
polarities of the first path and the second path of at least some semiconductor devices are different from polarities of other semiconductor devices.
